(19) United States
(12) Patent Application Publication
(10) Pub. No.: US 2013/0128419 A1
(43) Pub. Date: May 23, 2013

(54) OPTICAL FILM AND BACKLIGHT MODULE

(71) Applicant: Shuang Lu, Shenzhen (CN)

(72) Inventor: Shuang Lu, Shenzhen (CN)

(73) Assignee: SHENZHEN CHINA STAR OPTOELECTRONICS TECHNOLOGY CO.,LTD., SHENZHEN (CN)

(21) Appl. No.: 13/378,476

(22) PCT Filed: Nov. 29, 2011
(86) PCT No.: PCT/CN2011/083176

§ 371 Date: Dec. 15, 2011

(30) Foreign Application Priority Data
Nov. 18, 2011 (CN) 201120461801.X

(51) Int. Cl. H05K 7/00; B32B 3/10

(52) U.S. Cl. 361/679.01; 428/138; 428/174

(57) ABSTRACT

An optical film includes a body and positioning members which are disposed separately. The positioning member includes a first fixing portion connected with the body and a second fixing portion. A backlight module includes a back plate and the optical film. The optical film includes a body and positioning members which are disposed separately. The positioning member includes a first fixing portion connected with the body and a second fixing portion connected with the back plate. The body and the positioning members of the optical film are disposed separately in the present disclosure, thereby reducing the cost incurred by the die-cut of the optical film in the prior art. The positioning member is disposed independently at any position of the body and replaced according to the specific requirement, so the assembly is easy and convenient and can be applied flexibly.

BACKGROUND

1. Technical Field

The present disclosure relates to the field of liquid crystal display technology, and more particularly relates to an optical film and a backlight module.

2. Description of Related Art

Liquid crystal display (LCD) is a kind of flat panel display (FPD) that display images by using characteristics of a liquid crystal material. The LCD display has the advantages of thin and light, low driving voltage and low power consumption in comparison with other display apparatus and has become the mainstream product on the consumption market.

The LCD apparatus mainly includes an LCD panel and a backlight module. The liquid crystal of the LCD panel cannot emit light by itself, so the LCD panel needs to be lightened by a light source of the backlight module to achieve the purpose of displaying. To improve the display effect of the liquid crystal display device, normally, an optical film is applied in the LCD apparatus.

The optical film is connected to a back plate of the backlight module in a manner of riveting. As shown in FIG. 1, the optical film 100 includes a body 101 and multiple positioning portions 102. The positioning portion 102 protrudes from edges of the body 101, and is provided with the positioning holes 1021. Accordingly, a riveting stud 201 is disposed at the position where the back plate 200 and the optical film 100 are fixed. In the assembling, the optical film 100 and the back plate 200 are aligned, and the riveting stud 201 of the back plate 200 penetrates the positioning hole 1021 of the positioning portion 102, so as to fix the optical film 100 and the back plate 200. Although this connection method enables the optical film 100 and the back plate 200 assembled conveniently, the optical film 100 needs a die-cut, which increases the using cost of the film material and the difficulty in cutting.

### SUMMARY

The primary objective of the present disclosure is to provide an optical film, thereby reducing the manufacturing cost of the optical film.

The present disclosure provides an optical film, which includes a body and positioning members. The body and the positioning members are disposed separately, and the positioning member includes a first fixing portion and a second fixing portion. The first fixing portion is permanently connected with the body.

Preferably, the first fixing portion is provided with an adhesive.

Preferably, the second fixing portion is provided with a fixing hole.

Preferably, the second fixing portion is bent and extends from an edge of the first fixing portion to present a hook shape.

Preferably, the number of the positioning member is multiple.

The present disclosure also provides a backlight module, which includes a back plate and an optical film. The optical film includes a body and positioning members. The body and the positioning members are disposed separately, and the positioning member includes a first fixing portion permanently connected with the body and a second fixing portion permanently connected with the back plate. The first fixing portion is provided with an adhesive. The back plate includes a third fixing portion fit-fixed with the second fixing portion.

Preferably, the second fixing portion is provided with a fixing hole, and the third fixing portion is a riveting stud vertically protruding on the back plate. The fixing hole of the second fixing portion is correspondingly sleeved on the riveting stud to fix the back plate and the optical film.

Preferably, the second fixing portion has a fixing hole, and the third fixing portion is a screw hole arranged on the back plate. A rivet penetrates the fixing hole and is fixed in the screw hole to fix the back plate and the optical film.

Preferably, the second fixing portion is bent and extends from an edge of the first fixing portion to present a hook shape. The back plate further includes a back plate main body. The back plate main body vertically protrudes to form the third fixing portion, and the second fixing portion is retained on the third fixing portion to fix the back plate and the optical film.

The present disclosure further provides a backlight module, which includes a back plate and an optical film. The optical film includes a body and positioning members. The body and the positioning members are disposed separately, and the positioning member includes a first fixing portion permanently connected with the body and a second fixing portion permanently connected with the back plate.

Preferably, the first fixing portion is provided with an adhesive.

Preferably, the second fixing portion is provided with a fixing hole. The back plate is provided with a third fixing portion. The third fixing portion is fit-fixed with the second fixing portion.

Preferably, the third fixing portion is a riveting stud vertically protruding on the back plate or a screw hole arranged on the back plate.

Preferably, the second fixing portion is bent and extends from an edge of the first fixing portion to present hook shape. The back plate is provided with a third fixing portion. The second fixing portion is fit-fixed with the third fixing portion.

Preferably, the back plate includes a back plate main body. The back plate main body vertically protrudes to form the third fixing portion.

In the present disclosure, the body and the positioning members of the optical film are disposed separately, thereby avoiding the cost problem incurred by the die-cut of the optical film in the prior art and saving the cost. The positioning member is disposed independently, and can be disposed at any position of the body and replaced according to the specific requirement, so the assembly is easy and convenient and can be applied flexibly.

### BRIEF DESCRIPTION OF THE DRAWINGS

FIG. 1 is a schematic structural view of an optical film in the prior art;

FIG. 2 is a schematic structural view of a body of an optical film according to an embodiment of the present disclosure;

FIG. 3 is a schematic structural view of a positioning member of the optical film according to an embodiment of the present disclosure;

FIG. 4 is a schematic structural view of a backlight module according to an embodiment of the present disclosure;

FIG. 5 is a schematic structural view of a positioning member of the optical film according to another embodiment of the present disclosure; and

FIG. 6 is a schematic structural view of the backlight module according to another embodiment of the present disclosure.

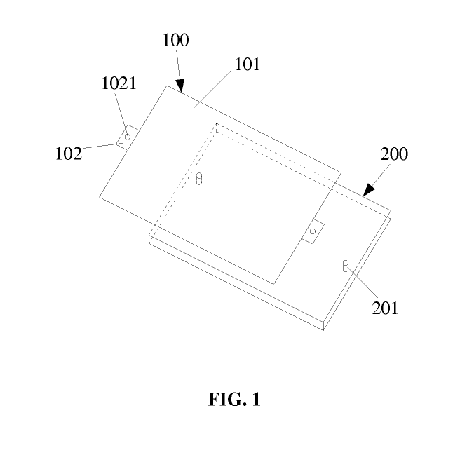

### DETAILED DESCRIPTION

To make the objectives, technical solutions, and advantages of the present disclosure become more apparent, the present disclosure is further described below in detail with reference to the accompanying drawings and embodiments. It should be understood that, the specific embodiments described herein are mainly intended to demonstrate the present disclosure, instead of restricting the present disclosure.

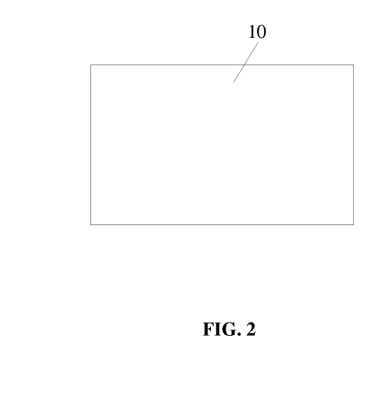

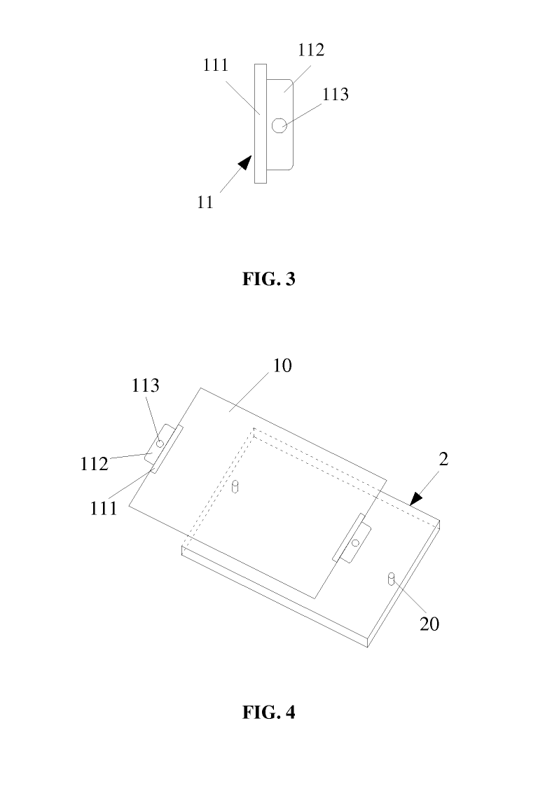

Referring to FIGS. 2 and 3, FIG. 2 is a schematic structural view of a body of an optical film according to an embodiment of the present disclosure and FIG. 3 is a schematic structural view of a positioning member of the optical film according to an embodiment of the present disclosure. The optical film includes the body 10 and the positioning members 11. The positioning member 11 includes a first fixing portion 111. The first fixing portion 111 is permanently connected with the body 10. The positioning member 11 further includes a second fixing portion 112. The second fixing portion 112 is provided with a fixing hole 113.

The first fixing portion 111 is provided with an adhesive. The body 10 is a regular quadrilateral and may be formed one-piece formed by die cutting. The positioning member 11 may be disposed at any position of the body 10 by the adhesive of the first fixing portion 111, so the assembly is easy and convenient. In addition, the body 10 and the positioning member 11 are disposed separately. Therefore, if the positioning member 11 is damaged, only the positioning member 11 is replaced instead of replacing the entire optical film, thus reducing the manufacturing cost of the optical film.

In this embodiment, the body 10 and the positioning member 11 of the optical film are disposed separately, thereby avoiding the cost problem incurred by the die-cut of the optical film in the prior art and reducing the cost. Moreover, the positioning member can be disposed independently, and can be disposed at any position of the body 10 and replaced according to the specific requirement, so the assembly is easy and convenient and can be applied flexibly.

Referring to FIGS. 2 to 4 together, FIG. 4 is a schematic structural view of a backlight module according to an embodiment of the present disclosure. The backlight module includes the optical film and a back plate 2. The second fixing portion 112 of the optical film is provided with the fixing hole 113, and the back plate 2 is provided with a third fixing portion 20 corresponding to the fixing hole 113. The third fixing portion 20 may be a riveting stud vertically protruding on the back plate 2. The fixing hole 113 of the second fixing portion 112 is correspondingly sleeved on the riveting stud, thereby fixing the back plate 2 and the optical film. The third fixing portion 20 may also be a screw hole arranged on the back plate 2. A rivet penetrates the fixing hole 113 and is fixed in the screw hole, thereby fixing the back plate 2 and the optical film.

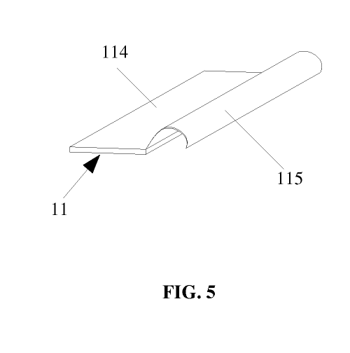

Referring to FIG. 5, FIG. 5 is a schematic structural view of a positioning member of the optical film according to another embodiment of the present disclosure. In the embodiment, the positioning member 11 includes a first fixing portion 114 and a second fixing portion 115. The first fixing portion 114 is provided with an adhesive. The positioning member 11 and the body 10 are permanently connected by the adhesive. The second fixing portion 115 is bent and extends from the edge of the first fixing portion 114 to present a hook shape.

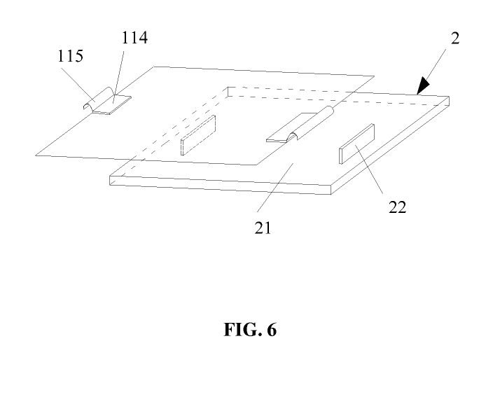

Referring to FIGS. 5 and 6 together, FIG. 6 is a schematic structural view of the backlight module according to another embodiment of the present disclosure. The backlight module includes the optical film and a back plate 2. The back plate 2 includes a back plate main body 21. The back plate main body 21 is provided with a third fixing portion 22 corresponding to the second fixing portion 112. The back plate main body 21 vertically protrudes to form the third fixing portion 22, and the second fixing portion 112 in the hook shape is retained on the third fixing portion 21, thereby fixing the back plate 2 and the optical film.

The above descriptions are merely taken as the preferred embodiment of the present disclosure, but not intended to restrict the present disclosure. Any modification, equivalent replacement, and improvement that fall within the spirit and principle of the present disclosure are included in the protection scope of the claims of the present disclosure.

What is claimed is:

1. An optical film, wherein the optical film comprises a body and positioning members, the body and the positioning members are disposed separately, and the positioning member comprises a first fixing portion and a second fixing portion, and the first fixing portion is permanently connected with the body.

2. The optical film of claim 1, wherein the first fixing portion is provided with an adhesive.

3. The optical film of claim 2, wherein the second fixing portion is provided with a fixing hole.

4. The optical film of claim 2, wherein the second fixing portion is bent and extends from an edge of the first fixing portion to present a hook shape.

5. The optical film of claim 1, wherein a number of the positioning member is multiple.

6. A backlight module, comprising a back plate and an optical film, wherein the optical film comprises a body and positioning members, the body and the positioning members are disposed separately, and the positioning member comprises a first fixing portion permanently connected with the body and a second fixing portion permanently connected with the back plate, the first fixing portion is provided with an adhesive, and the back plate comprises a third fixing portion fit-fixed with the second fixing portion.

7. The backlight module of claim 6, wherein the second fixing portion is provided with a fixing hole, the third fixing portion is a riveting stud vertically protruding on the back plate, the fixing hole of the second fixing portion is correspondingly sleeved on the riveting stud to fix the back plate and the optical film.

8. The backlight module of claim 6, wherein the second fixing portion has a fixing hole, the third fixing portion is a screw hole arranged on the back plate, and a rivet penetrates the fixing hole and is fixed in the screw hole to fix the back plate and the optical film.

9. The backlight module of claim 6, wherein the second fixing portion is bent and extends from an edge of the first fixing portion to present a hook shape, the back plate further comprises a back plate main body, the back plate main body vertically protrudes to form the third fixing portion, and the second fixing portion is retained on the third fixing portion to fix the back plate and the optical film.

10. A backlight module, comprising a back plate and an optical film, wherein the optical film comprises a body and positioning members, the body and the positioning members are disposed separately, and the positioning member comprises a first fixing portion permanently connected with the body and a second fixing portion permanently connected with the back plate.

11. The backlight module of claim 10, wherein the first fixing portion is provided with an adhesive.

12. The backlight module of claim 10, wherein the second fixing portion is provided with a fixing hole, the back plate is provided with a third fixing portion, and the third fixing portion is fit-fixed with the second fixing portion.

13. The backlight module of claim 12, wherein the third fixing portion is a riveting stud vertically protruding on the back plate or a screw hole arranged on the back plate.

14. The backlight module of claim 10, wherein the second fixing portion is bent and extends from an edge of the first fixing portion to present a hook shape, the back plate is provided with a third fixing portion, and the second fixing portion is fit-fixed with the third fixing portion.

15. The backlight module of claim 14, wherein the back plate comprises a back plate main body, and the back plate main body vertically protrudes to form the third fixing portion.
